(19) United States
(12) Patent Application Publication
(10) Pub. No.: US 2011/0203648 A1
(43) Pub. Date: Aug. 25, 2011

(54) LASER PROCESSED HETEROJUNCTION PHOTOVOLTAIC DEVICES AND ASSOCIATED METHODS

(76) Inventors: James Carey, Waltham, MA (US); Martin U. Pralle, Wayland, MA (US)

(21) Appl. No.: 12/860,715

(22) Filed: Aug. 20, 2010

Related U.S. Application Data
(60) Provisional application No. 61/235,556, filed on Aug. 20, 2009.

(51) Int. Cl. H01L 31/06; H01L 31/0352; H01L 31/072

(52) U.S. Cl. 136/255; 438/87; 257/E31.032

(57) ABSTRACT

Heterojunction devices and associated methods of making and using are provided. In one aspect, for example, a heterojunction photovoltaic device can include a crystalline semiconductor layer, a first doped semiconductor layer coupled to the crystalline semiconductor layer, and a second doped semiconductor layer coupled to the crystalline semiconductor layer opposite the first doped semiconductor layer. The first and second doped semiconductor layers form junctions with the semiconductor layer. The device can further include a laser processed semiconductor region coupled to the crystalline semiconductor layer.

### PRIORITY DATA

This application claims the benefit of U.S. Provisional Patent Application Ser. No. 61/235,556, filed on Aug. 20, 2009, which is incorporated herein by reference.

### BACKGROUND

Various semiconductor devices can be used to absorb and detect photons. Such photo-detecting semiconductor devices are often affected by and provide some response to interaction with electromagnetic radiation. Various ranges of electromagnetic radiation can be detected by various photo-detecting semiconductor devices, including visible range wavelengths (approximately 400 nm to 700 nm) and non-visible wavelengths (longer than about 700 nm or shorter than 400 nm). The infrared spectrum is often thought of as including a near infrared portion of spectrum including wavelengths of approximately 700 to 1300 nm, a short wave infrared portion of the spectrum including wavelengths of approximately 1300 nm to 3 micrometers, and a mid to long wave infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

A heterojunction cell is a low doped single crystal silicon wafer that is coated on either side with a highly doped amorphous silicon layer, n-type on one side of the wafer and p-type on the other. The fundamental advantage of this structure is that it provides is a solar cell with a high open circuit voltage, >0.65V. This is a function of two main contributing elements. The open circuit voltage is defined by the relationship shown in Equation I:

$${V}_{oc} = \frac{kT}{q} ln ( \frac{{j}_{sc}}{{j}_{o}} + 1 ) \qquad I$$

where j_{sc}, and jₒ are the short circuit current and the dark current respectively. The doped amorphous silicon that is deposited on the crystalline silicon passivates the surface states of the substrate material and thus reduces the dark current and increases the open circuit voltage as indicated by Equation I. As the dark current is reduced the open circuit voltage logarithmically increases.

Doping amorphous silicon during deposition enables very high doping concentrations in the semiconductor material (˜10¹⁹-10²⁰ /cm³). These high concentrations do not diffuse into the silicon material and hence a very sharp doped/undoped transition forms between the silicon wafer and the amorphous layer. In fact, this interface is nearly atomically sharp. These sharp transitions set up a strong field across the photovoltaic cell that promotes drift of carriers out of the device and into the circuit. This increases the carrier velocity and decreases recombination resulting in higher short circuit currents. The higher photocurrent yields higher open circuit voltage as indicated in Equation I.

### SUMMARY

The present disclosure provides photovoltaic heterojunction devices and associated methods. In one aspect for example, a heterojunction photovoltaic device is provided. Such a device can include a crystalline semiconductor layer, a first doped semiconductor layer coupled to the crystalline semiconductor layer, and a second doped semiconductor layer coupled to the crystalline semiconductor layer opposite the first doped semiconductor layer. The first and second doped semiconductor layers form junctions with the semiconductor layer. The device can further include a laser processed semiconductor region coupled to the crystalline semiconductor layer.

In one aspect, the laser processed semiconductor region has a substantially textured surface with surface features. The surface features can be micron-sized, nano-sized, or a combination of micron-sized and nano-sized. Additionally, the laser processed semiconductor region can be disposed in various locations within the device. For example, in one aspect the laser processed semiconductor region is disposed on the crystalline semiconductor layer between the first doped semiconductor layer and the crystalline semiconductor layer. In another aspect, the laser processed semiconductor region is disposed on the crystalline semiconductor layer between the second doped semiconductor layer and the crystalline semiconductor layer. In yet another aspect, the laser processed semiconductor region includes a first laser processed semiconductor region disposed on the crystalline semiconductor layer between the first doped semiconductor layer and the crystalline semiconductor layer and a second laser processed semiconductor region disposed on the crystalline semiconductor layer between the second doped semiconductor layer and the crystalline semiconductor layer. In a further aspect, the laser processed semiconductor region is formed within the crystalline semiconductor layer.

Various doped semiconductor layers are additionally contemplated according to various aspects of the present disclosure. In one aspect, for example, at least one of the first doped semiconductor layer and the second doped semiconductor layer is amorphous. In another aspect, at least one of the first doped semiconductor layer and the second doped semiconductor layer is amorphous silicon, amorphous germanium, or a combination or alloy thereof. In one specific aspect, the amorphous semiconductor material is silicon. In another aspect, at least one of the first doped semiconductor layer and the second doped semiconductor layer is a crystalline semiconductor layer.

The use of intrinsic layers is also contemplated various aspects of the present disclosure. In one aspect, for example, an intrinsic or i-type layer is disposed between the crystalline semiconductor layer and at least one of the first doped semiconductor layer and the second doped semiconductor layer. In another aspect, the i-type layer is amorphous.

Various crystalline semiconductor layer materials and configurations are contemplated for use according to aspects of the present disclosure. In one aspect, for example, the crystalline semiconductor layer includes a member selected from the group consisting of group IV materials, compounds and alloys comprised of materials from groups II and VI, compounds and alloys comprised of materials from groups III and V, and combinations thereof. In one aspect, the crystalline semiconductor layer is silicon. In another aspect, the crystalline semiconductor layer is multicrystalline, microcrystalline, nanocrystalline, or a combination thereof. In a more specific aspect, a multicrystalline semiconductor can have a minimum grain size of 50 nanometers. In yet another specific aspect, the crystalline semiconductor layer is monocrystalline. Additionally, crystalline semiconductor layer materials can be made according to a variety of manufacturing processes. Non-limiting examples include float zone (FZ), Magnetic Czochralski (MCZ), Czochralski (CZ) processes, as well as deposited semiconductor layers. Nonlimiting examples of deposition processes include vapor, physical, or any other known deposition technique. Furthermore, in some aspects the laser processed region has been formed and/or processed in a substantially oxygen-depleted environment.

The crystalline semiconductor layer can be of a variety of thicknesses according to various aspects of the present disclosure, and any thickness capable of forming a heterojunction is considered to be within the present scope. In one specific aspect, however, the crystalline semiconductor layer has a thickness of from about 0.1 μm to about 50 μm thick. In another specific aspect, the crystalline semiconductor layer has a thickness of less than or equal to about 10 μm thick.

The devices according to aspects of the present disclosure can also include carrier substrates to facilitate, among other things, manipulation and manufacture. In one aspect, for example, a carrier substrate can be coupled to either the first semiconductor layer or the second semiconductor layer. In another aspect, the carrier substrate can be a material such as glass, polymer materials, ceramic materials, metal foils, and combinations thereof. The carrier substrate can have varying levels of flexibility, from rigid to flexible. For example, in one aspect the carrier substrate can be sufficiently rigid to allow little if any planar deformation of the heterojunction device. In another aspect, the carrier substrate is a flexible substrate. Such a substrate can be as flexible as the heterojunction devices allow without damage.

Electrical contacts can be arranged in a variety of configurations, and any such configuration is considered to be within the present scope. In one aspect, for example, the device can include a first electrical contact electrically coupled to the first doped semiconductor layer and a second electrical contact electrically coupled to the second doped semiconductor layer, where the first electrical contact and the second electrical contact are same side contacts. In another aspect, the device can include a first electrical contact electrically coupled to the first doped semiconductor layer and a second electrical contact electrically coupled to the second doped semiconductor layer, where the first electrical contact and the second electrical contact are opposite side contacts.

In another aspect of the present disclosure, a heterojunction photovoltaic device can include a crystalline semiconductor layer, a doped semiconductor layer coupled to the crystalline semiconductor layer to form a junction, and a laser processed semiconductor region coupled to the crystalline semiconductor layer. The laser processed semiconductor region can be disposed in various locations within the device. For example, in one aspect the laser processed semiconductor region is disposed on the crystalline semiconductor layer between the doped semiconductor layer and the crystalline semiconductor layer. In another aspect, the laser processed semiconductor region is disposed on the crystalline semiconductor layer opposite the doped semiconductor layer. In yet another aspect, the laser processed semiconductor region can include a first laser processed semiconductor region disposed on the crystalline semiconductor layer between the doped semiconductor layer and the crystalline semiconductor layer and a second laser processed semiconductor region disposed on the crystalline semiconductor layer opposite the doped semiconductor layer. Additionally, the device can further include an i-type layer disposed between the doped semiconductor layer and the crystalline semiconductor layer.

In another aspect of the present disclosure, a method of making a heterojunction photovoltaic device is provided. Such a method includes laser processing a region of a crystalline semiconductor layer, depositing a first semiconductor layer on the crystalline semiconductor layer, and doping the first semiconductor layer. The method further includes depositing a second semiconductor layer on the crystalline semiconductor layer opposite the first semiconductor layer and doping the second semiconductor layer. In another aspect, the method can include annealing the crystalline semiconductor layer and the laser processed region. The doping of the doped semiconductor layers can be performed as a separate process, or doping can occur in situ during deposition. Additionally, in one aspect the method can further include forming an i-type layer between the first semiconductor layer and the second semiconductor layer.

Various laser processing techniques are contemplated. In one aspect, for example, the laser processing includes irradiating the crystalline semiconductor layer with laser radiation to form a substantially textured surface with surface features having a size selected from the group consisting of micro-sized, nano-sized, and combinations thereof. In another aspect, irradiating the crystalline semiconductor layer includes exposing the laser radiation to a dopant such that the irradiation incorporates the dopant into the crystalline semiconductor layer. In yet another aspect, the laser processing is performed using a pulsed laser. Various pulsed lasers are contemplated, including femtosecond lasers, picosecond lasers, and a nanosecond lasers.

In one aspect, the crystalline semiconductor layer has a low oxygen content and the laser processing and the annealing are performed in a substantially oxygen-depleted environment. In another aspect, the annealing of the crystalline semiconductor layer and the laser processed region is performed to a temperature of from about 300° C. to about 1100° C. In yet another aspect, the annealing of the crystalline semiconductor layer and the laser processed region is performed to a temperature of from about 500° C. to about 900° C.

### BRIEF DESCRIPTION OF THE DRAWINGS

FIG. 1 is a schematic view of a heterojunction device in accordance with one aspect of the present disclosure;

FIG. 2 is a schematic view of a heterojunction device in accordance with another aspect of the present disclosure;

FIG. 3 is a schematic view of a heterojunction device in accordance with yet another aspect of the present disclosure;

FIG. 4 is a schematic view of a heterojunction device in accordance with a further aspect of the present disclosure;

FIG. 5 is a schematic view of a heterojunction device in accordance with yet a further aspect of the present disclosure;

FIG. 6 is a schematic view of a heterojunction device in accordance with another aspect of the present disclosure;

FIG. 7 is a schematic view of a heterojunction device in accordance with yet another aspect of the present disclosure;

FIG. 8 is a schematic view of a heterojunction device in accordance with a further aspect of the present disclosure;

FIG. 9 is a schematic view of a heterojunction device in accordance with yet a further aspect of the present disclosure; and

FIG. 10 is a flow diagram of a method of making a heterojunction device in accordance with another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

In describing and claiming the present disclosure, the following terminology will be used in accordance with the definitions set forth below.

As used herein, the term “low oxygen content” refers to any material having an interstitial oxygen content that is less than or equal to about 60 ppm atomic.

As used herein, the terms “disordered surface” and “textured surface” can be used interchangeably, and refer to a surface having a topology with nano- to micron-sized surface texture formed by the irradiation of laser pulses. While the characteristics of such a surface can be highly variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized crystal structures (e.g. about 2 μm to about 60 μm). In another aspect, the disordered surface can have a topology having texture ranging from 0.1 nm to 1000 μm in size. In yet another aspect, the disordered surface can have a topology having texture ranging from 0.1 nm to 100 μm in size.

As used herein, the term “fluence” refers to the amount of energy from a single pulse of laser radiation that passes through a unit area. In other words, “fluence” can be described as the energy density of one laser pulse.

As used herein, the terms “surface modifying” and “surface modification” refer to the altering of a surface of a semiconductor material using laser radiation. Surface modification can include processes using primarily laser radiation or laser radiation in combination with a dopant, whereby the laser radiation facilitates the incorporation of the dopant into a surface of the semiconductor material. Accordingly, in one aspect surface modification includes doping of a semiconductor material.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

The term “coupled” as used herein includes both direct coupling and indirect coupling through an intermediate layer or layers. Thus, for example, when referring to a doped semiconductor layer being coupled to a crystalline semiconductor layer, it can be directly coupled thereto, or through an intermediate layer.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of particles would either completely lack particles, or so nearly completely lack particles that the effect would be the same as if it completely lacked particles. In other words, a composition that is “substantially free of an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

It is noted that when discussing the present heterojunction photovoltaic devices, systems, and associated methods, each of these discussions can be considered applicable to each of the other embodiments, whether or not they are explicitly discussed in the context of that embodiment. Thus, for example, in discussing a specific structure used in the device, such a structure can also be used in the method of manufacturing the device, and vice versa. Also, in discussing specific details with respect to one specific device, such details are also applicable to other device embodiments.

The Disclosure

The present disclosure provides heterojunction photovoltaic devices and associated methods, where the bulk of semiconductor substrate is thinner than in traditional thick semiconductor photovoltaic devices. Thus, the devices of the present disclosure have a thin film heterojunction architecture having improved light absorption capabilities. One of the primary loss mechanisms in traditional thin-film photovoltaic devices is the tendency of such thin-film junctions transmit rather than absorb a significant amount of light. It has been recognized that a laser processed region or layer disposed within the heterojunction improves performance. Thus the increased absorption of light improves the overall efficiency of devices incorporating such heterojunctions therein. In addition to improving performance, a heterojunction device of the present disclosure can be made using significantly less raw materials as compared to prior heterojunction devices.

Traditional thin film silicon solar cells exhibit limited light absorbing characteristics. In the case of amorphous silicon, for example, the band gap is such that light beyond 750 nm is not absorbed (as compared to 1100 nm for thick crystalline silicon). The solar spectrum has more than 50% of its energy in wavelengths longer than 750 nm. Therefore, a very large portion of the solar spectrum is not converted to electricity in thin-film amorphous solar cells. The present disclosure provides a heterojunction photovoltaic device utilizing thin semiconductor layers and a laser processed region that significantly increases the range of wavelengths absorbed, thus allowing efficient light absorption. This laser processed region thus increases performance of the device, as more light is captured. It should be noted, however, that the present scope is not limited to thin layers of semiconductor materials, and that the principles disclosed herein apply to semiconductor materials of all thicknesses.

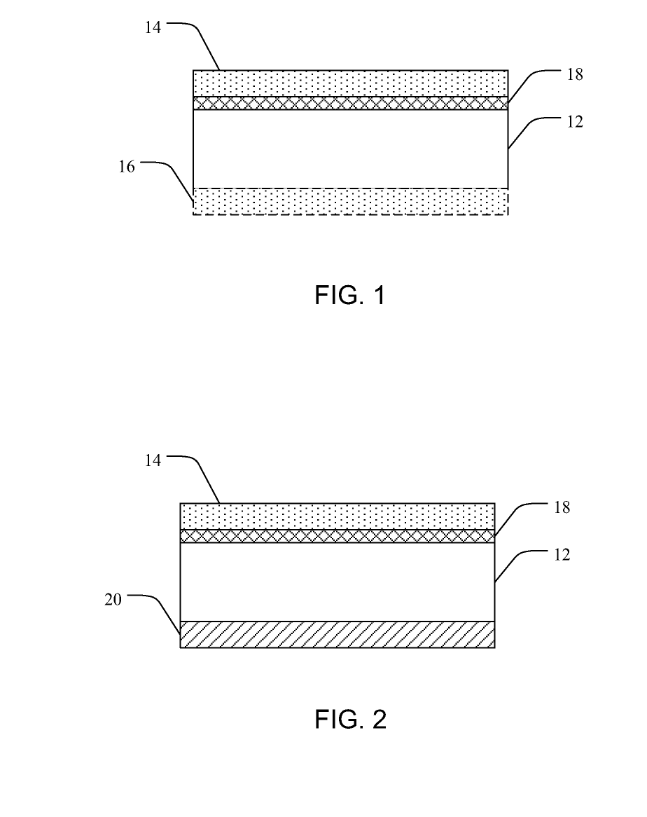

In one aspect of the present disclosure, a heterojunction photovoltaic device is shown in FIG. 1. The device can include a crystalline semiconductor layer 12, a first doped semiconductor layer 14 coupled to the crystalline semiconductor layer, and a second doped semiconductor layer 16 coupled to the crystalline semiconductor layer opposite the first doped semiconductor layer. The first and second doped semiconductor layers form junctions with the crystalline semiconductor layer. In some aspects, the first and second doped semiconductor layers are relatively doped to form junctions with the crystalline semiconductor layer. It should be noted that in some aspects, the second doped semiconductor layer 16 may not be present, as is denoted by the dashed line in FIG. 1. Additionally, the device further includes a laser processed semiconductor region 18 coupled to the crystalline semiconductor layer. Electrical contacts 19 can also be associated with the device, with one contact being electrically coupled to the first doped semiconductor layer and another contact being electrically coupled to the second doped semiconductor layer.

A variety of crystalline semiconductor layer materials are contemplated for use with the methods and devices according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the crystalline semiconductor material can be or include silicon. In another aspect, the crystalline semiconductor material can include at least one of silicon, carbon, germanium, aluminum nitride, gallium nitride, indium gallium arsenide, aluminum gallium arsenide, and combinations thereof.

Exemplary group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The crystalline semiconductor layer can be of any thickness that allows heterojunction functionality, and thus any such thickness of semiconductor material is considered to be within the present scope. However, the laser processed region of the semiconductor increases the efficiency of the device such that the crystalline semiconductor layer can be significantly thinner than has previously been possible. Decreasing the thickness of the crystalline semiconductor reduces the amount of the often costly semiconductor material required to make such a device. In one aspect, for example, the crystalline semiconductor layer has a thickness of from about 0.1 μm to about 50 μm. In another aspect, the crystalline semiconductor layer has a thickness of from about 0.01 μm to about 100 μm. In yet another aspect, the crystalline semiconductor layer has a thickness of less than or equal to about 100 μm. In a further aspect, the crystalline semiconductor layer has a thickness of from about 0.01 μm to about 10 μm. In yet another aspect, the crystalline semiconductor layer has a thickness of less than or equal to about 10 μm. In a further aspect, the crystalline semiconductor layer has a thickness of from about 0.01 μm to about 1 μm. Such thin semiconductor materials can allow the manufacture of heterojunction devices that are less than or equal to 1 μm thick.

Additionally, various types of crystalline semiconductor material are contemplated, and any such material that can be incorporated into a heterojunction device is considered to be within the present scope. In one aspect, for example, the crystalline semiconductor is monocrystalline. In another aspect, the crystalline semiconductor is multicrystalline, nanocrystalline, microcrystalline, or a combination thereof.

The crystalline semiconductor materials of the present disclosure can be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth processes, and the like. Various deposition processes are contemplated, and any known deposition method is considered to be within the present scope. Whether or not low oxygen content is desired in the heterojunction device can also affect the choice of a manufacturing process for the crystalline semiconductor material. Various processes produce semiconductor materials containing varying amounts of oxygen, and as such, some applications having more stringent tolerances with respect to oxygen levels may benefit more from certain manufacturing procedures as compared to others. For example, during CZ crystal growth oxygen from the containment vessel, usually a quartz crucible, can become incorporated into the crystal as it is pulled. Additionally, other sources of oxygen contamination are also possible with the CZ process. Such contamination may be reduced, however, through the use of non oxygen-containing crucible materials, as well as the development of other crystal growth methods that do not utilize a crucible. One such process is the FZ process.

Substrates grown with the CZ method can also be made to have lowered oxygen concentration through enhancements to the crystal growth process, such as growing the crystal in the presence of a magnetic field (i.e. the mCz process). Also, gettering techniques can be employed to reduce the impact of oxygen or other impurities on the finished device. These gettering techniques can include thermal cycles to liberate or nucleate impurities, or selective ion implantation of species to serve as gettering sites for the impurities. For example, oxygen concentrated in the semiconductor can be removed by the performing a furnace cycle to form a denuded zone. During heating with an inert gas, oxygen near the surface of the semiconductor diffuses out of the material. During the furnace cycle but after the denuding step, nucleating and growing steps may be performed. Nucleating sites for precipitates are formed during the nucleating step, and the precipitates are grown from the nucleating sites during a growing step. The precipitates are formed from interstitial oxygen within the bulk of the semiconductor material and beneath the denuded zone. The precipitation of oxygen in the bulk of semiconductor material can be desired because such precipitates can act as gettering sites. Such precipitate formation can also be performed to “lock up” interstitial oxygen into the precipitates and reduce the likelihood that such oxygen can migrates from the bulk of the semiconductor material into the denuded zone.

In those aspects whereby low oxygen content of the heterojunction device is desired, further processing of the crystalline semiconductor material can be performed so as to minimize the introduction of oxygen. Oxygen can exist in different states or at different sites (for example, interstitially or substitutionally) within a semiconductor such as silicon, dependent upon the thermal processing the semiconductor has received. If the semiconductor is subjected to temperatures higher than, for example, about 1000° C., oxygen can form aggregates or clusters that serve as defect sites in the crystal lattice. These sites may result in trap states and a reduction in carrier lifetime within the semiconductor substrate and device. At lower temperatures (for example, around 400° C. to 700° C.), oxygen can behave as electrically active thermal donors. Thus, oxygen can have a negative impact on carrier lifetime and on carrier mobility. In a device fabricated to have photoconductive gain, the presence of oxygen causing reduced carrier lifetime may result in reduced levels of photoconductive gain.

It may be beneficial, therefore, to produce various semiconductor devices such that a low oxygen content is obtained or maintained. This can be accomplished in a variety of ways, including using crystalline semiconductor materials having low levels of oxygen contained therein, processing these materials in a manner that minimizes the uptake of oxygen into the semiconductor lattice, and utilizing techniques that eliminate or reduce oxygen that may be present in the semiconductor. Such processes and techniques can include, for example, annealing the annealing of the crystalline semiconductor layer and the laser processed region to lower temperatures as compared to previous annealing procedures. In one aspect, an exemplary annealing temperature is from about 300° C. to about 1100° C. In another aspect, such an annealing temperature range is from about 500° C. to about 900° C.

Additionally, laser processing of the crystalline semiconductor and/or the annealing process can be performed in a substantially oxygen-depleted environment in order to minimize the introduction of oxygen into the semiconductor. An oxygen-depleted or substantially oxygen-depleted environment can include a variety of environments. In one aspect, for example, the oxygen-depleted environment can be an environment whereby oxygen from the air or other sources has been replaced with a gas or other fluid containing little to no oxygen. In another aspect, processing can occur in a vacuum environment, and thus contain little to no oxygen. Additionally, oxygen-containing materials or materials that introduce oxygen into the semiconductor, such as, for example, quartz crucibles, can be avoided. As a practical matter, the term “oxygen-depleted environment” can be used to describe an environment with low levels of oxygen, provided a semiconductor material can be processed therein within the desired tolerances. Thus, environments having low oxygen, or little to no oxygen, are environments in which a semiconductor can be processed as a low-oxygen content semiconductor while maintaining oxygen levels within the tolerances of the present disclosure. In one aspect, an oxygen-depleted environment can be an oxygen-free environment. Further details regarding low-oxygen content semiconductor materials can be found in U.S. patent application Ser. No. 12/771,848, filed on Apr. 30, 2010, which is incorporated herein by reference.

The crystalline semiconductor material can have varying levels of oxygen depending on the desired efficiency of the device. In some aspects, oxygen content may be of no concern, and thus any level of oxygen within the lattice is acceptable. In other aspects, a low oxygen content is desired. In one aspect a crystalline semiconductor material can have an oxygen content that is less than or equal to about 50 ppm atomic. In another aspect, a crystalline semiconductor material can have an oxygen content that is less than or equal to about 30 ppm atomic. In yet another aspect, the crystalline semiconductor material can have an oxygen content less than or equal to about 10 ppm atomic. In another aspect the crystalline semiconductor can have an oxygen content less than about 5 ppm atomic. In yet another aspect, the crystalline semiconductor can have an oxygen content less than about 1 ppm atomic.

The devices according to aspects of the present disclosure can include one or more doped semiconductor layers. These doped semiconductor layers can be either amorphous or crystalline materials. As is shown in FIG. 1, for example, the first doped semiconductor layer 14 and the second doped semiconductor layer 16 are both amorphous materials. FIG. 2 shows an embodiment whereby an amorphous doped semiconductor layer 14 is coupled to the crystalline semiconductor layer 12, and a crystalline doped semiconductor layer 20 is coupled to the crystalline semiconductor layer opposite the amorphous doped semiconductor layer. A laser processed semiconductor region 18 is disposed between the crystalline semiconductor layer and the amorphous doped semiconductor layer. Alternatively, the laser processed semiconductor region can be disposed between the crystalline semiconductor layer and the crystalline doped semiconductor layer, or the device can include a first laser processed semiconductor region disposed between the crystalline semiconductor layer and the crystalline doped semiconductor layer and a second laser processed semiconductor region disposed between the crystalline semiconductor layer and the amorphous doped semiconductor layer (not shown).

The doped semiconductor layers according to aspects of the present disclosure can be produced by any method capable of depositing such materials so as to function as a heterojunction device. In one aspect, a doped semiconductor layer can be deposited using chemical vapor deposition (CVD). CVD deposition allows the formation of semiconductor materials that are very thin, in some cases to less than a few μm thick. In one aspect, the doped semiconductor layer can be epitaxially deposited on the crystalline semiconductor layer. The formation of junctions with such thinly deposited materials allows for the manufacture of thin flexible devices, as well as a significant reduction in manufacturing materials. Thus the thicknesses of the doped semiconductor layers can vary depending on the intended use of the resulting devices, and the present scope should not be limited by the thicknesses such materials. In one aspect, however, a doped semiconductor layer can have a thickness of from about 0.01 μm to about 10 μm. In another aspect, a doped semiconductor layer can have a thickness of less than about 5 μm. In yet another aspect, a doped semiconductor layer can have a thickness of less than about 2 μm. In a further aspect, a doped semiconductor layer can have a thickness of less than about 1 μm.

The doped semiconductor layer materials according to aspects of the present disclosure are generally silicon materials, although any material capable of forming a heterojunction with the crystalline semiconductor layer is considered to be within the present scope. In one aspect, germanium and silicon/germanium combinations and alloys thereof are also contemplated. As has been described, the doped semiconductor layers can be amorphous or crystalline. Thus, in the case of silicon, amorphous silicon materials and crystalline silicon materials can be utilized. The doping of such materials is discussed in more detail below.

Additionally, a passivation region or layer can be included in the various devices of the present disclosure to, among other things, reduce surface recombination in the device and provide anti-reflective properties. The passivation layer can be disposed on the doped semiconductor layer or layers, the crystalline semiconductor layer, and/or the laser processed semiconductor region. It should be noted that any region, layer, or material of the device that can be passivated is considered to be within the present scope. The layer can be any material capable of providing passivating properties to the device, and any such material is considered to be within the present scope. Nonlimiting examples of passivation layers can include oxides or nitrides. Specific examples include silicon oxide and silicon nitride,

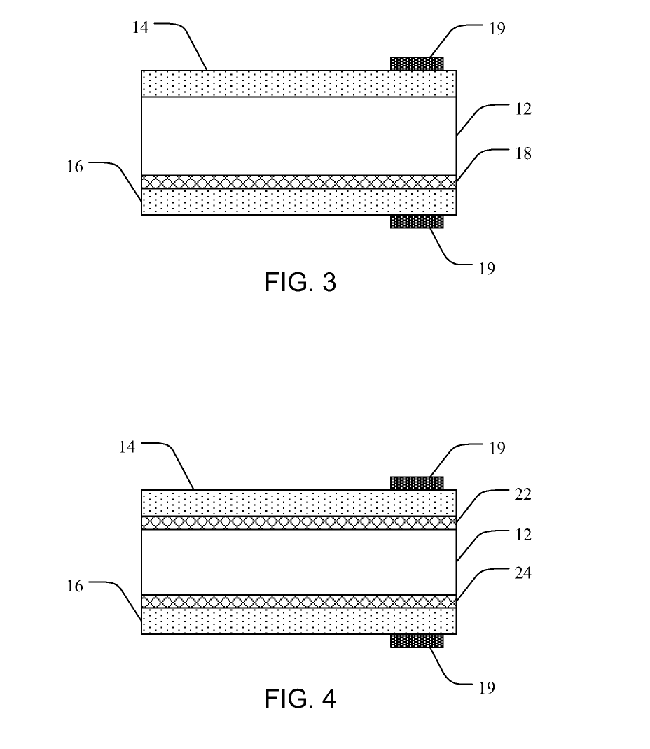

In another aspect, as is shown in FIG. 3, a first doped semiconductor layer 14 is coupled to a crystalline semiconductor layer 12. A second doped semiconductor layer 16 is coupled to the crystalline semiconductor layer opposite the first doped semiconductor layer. In this case, both the first and second doped semiconductor layers are amorphous, though one or both of these layers could be crystalline or other type of doped semiconductor layer. A laser processed semiconductor region 18 is disposed between the crystalline semiconductor layer and the second doped amorphous semiconductor layer. Thus, as is shown in FIGS. 1 and 3, the laser processed semiconductor region can be disposed on either side of the crystalline semiconductor layer, either adjacent to the first doped semiconductor layer or adjacent to the second doped semiconductor layer. Additionally, electrical contacts 19 can also be associated with the device, with one contact being electrically coupled to the first doped semiconductor layer and another contact being electrically coupled to the second doped semiconductor layer.

In yet another aspect, as is shown in FIG. 4, the laser processed semiconductor region can include a first laser processed semiconductor region 22 disposed on the crystalline semiconductor layer between the first doped semiconductor layer and the crystalline semiconductor layer, and a second laser processed semiconductor region 24 disposed on the crystalline semiconductor layer between the second doped semiconductor layer and the crystalline semiconductor layer. Additionally, in some aspects, the laser processed semiconductor region can be formed within the crystalline semiconductor layer (not shown).

A variety of techniques of forming a laser processed semiconductor region on the crystalline semiconductor layer are contemplated, and any technique capable of forming such a region should be considered to be within the present scope. In one aspect, for example, a target region of the crystalline semiconductor material can be irradiated with laser radiation to form a laser processed region. Examples of such processing have been described in further detail in U.S. Pat. Nos. 7,057,256, 7,354,792 and 7,442,629, which are incorporated herein by reference in their entireties. Briefly, a surface of a semiconductor material is irradiated with laser radiation to form a textured or surface modified region. Such laser processing can occur with or without a dopant material. In those aspects where a dopant is used, the laser can be directed through a dopant carrier and onto the semiconductor surface. In this way, dopant from the dopant carrier is introduced into the target region of the semiconductor material. Such a region incorporated into a semiconductor material can have various benefits in accordance with aspects of the present disclosure. For example, the region typically has a textured surface that increases the surface area of the laser processed region and increases the probability of photon absorption. In one aspect, such a region is a substantially textured surface including micron-sized and/or nano-sized surface features that have been generated by the laser texturing. In another aspect, irradiating the surface of crystalline semiconductor material includes exposing the laser radiation to a dopant such that irradiation incorporates the dopant into the semiconductor. Various dopant materials are known in the art, and are discussed in more detail herein.

The type of laser radiation used to surface modify a semiconductor material can vary depending on the material and the intended modification. Any laser radiation known in the art can be used with the systems and methods of the present disclosure. There are a number of laser characteristics that can affect the surface modification process and/or the resulting product including, but not limited to the wavelength of the laser radiation, pulse width, pulse fluence, pulse frequency, polarization, laser propagation direction relative to the semiconductor material, etc. In one aspect, a laser can be configured to provide pulsatile lasing of a semiconductor material. Such laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths are in the range of from about 50 to 500 femtoseconds.

The number of laser pulses irradiating a semiconductor target region can be in a range of from about 1 to about 2000. In one aspect, the number of laser pulses irradiating a semiconductor target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

n-type and p-type materials can be made by doping as well. In the case of n-type materials, doping creates an increase in the number of free negative charge carriers. In the case of p-type materials, doping creates an increase in the number of free positive charge carriers. In some aspects, variations of n(−−), n(−), n(+), n(++), p(−−), p(−), p(+), or p(++) type semiconductor layers may be used, whereby minus and positive signs are indicators of the relative strength of the doping of the semiconductor material. An intrinsic (i-type) semiconductor is typically a substantially undoped semiconductor. It is also contemplated that the different layers or regions may vary in oxygen content.

A variety of dopant materials are contemplated, and any such material that can be used to surface modify a semiconductor material according to aspects of the present disclosure is considered to be within the present scope. It should be noted that the particular dopant utilized can vary depending on the semiconductor being surface modified, and the intended use of the resulting semiconductor material. A dopants can be either electron donating or hole donating. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. Non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of 5.0×10⁻⁸ mol/cm³-5.0×10⁻⁴ mol/cm³. SF₆ gas is a good carrier for the incorporation of sulfur into the semiconductor material via a laser process without significant adverse effects on the semiconductor material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

Furthermore, the heterojunction devices of the present disclosure can include multiple layers that vary in majority carrier polarity (i.e. donor or acceptor impurities). The donor or acceptor impurities are often determined by the type of dopant/impurities introduced into the semiconductor either through a growth process, deposition process, epitaxial process, implant process, lasing process, or other known process to those skilled in the art. Often, semiconductor materials can include an n-type layer, an intrinsic (i-type) layer, and a p-type layer. These layers together can collectively be referred to as a p-i-n semiconductor material stack that creates a junction. A semiconductor material devoid of an i-type layer is also contemplated.

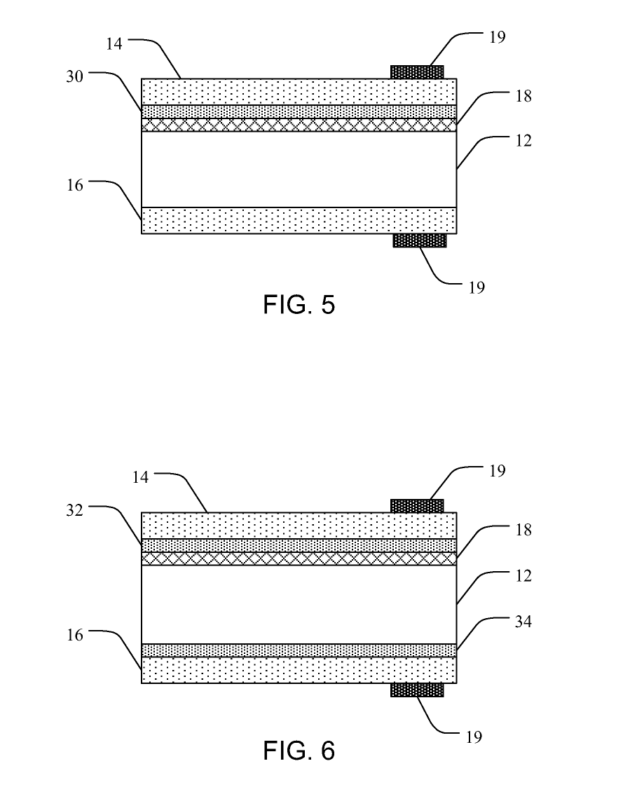

Regarding the configuration of an i-type layer within a heterojunction device, the present scope includes any relative spatial location that allows semiconductive functionality. For example, in one aspect as is shown in FIG. 5, an i-type layer 30 can be disposed between the laser processed semiconductor region 18 and the first doped semiconductor layer 14. In an alternative aspect, the i-type layer can be disposed between the crystalline semiconductor layer 12 and the second doped semiconductor layer 16 (not shown). As another example, FIG. 6 shows a first i-type layer 32 disposed between the laser processed semiconductor region 18 and the first doped semiconductor layer 14, and a second i-type layer 34 disposed between the laser processed semiconductor region and the second doped semiconductor layer 60. It is also contemplated then a second laser processed semiconductor region could be located between the second i-type layer and the crystalline semiconductor layer 12 (not shown).

The i-type layer materials according to aspects of the present disclosure are generally silicon materials, although any material capable of utilization in a heterojunction is considered to be within the present scope. In one aspect, germanium and silicon/germanium combinations and alloys thereof are also contemplated. The i-type layer can be amorphous or crystalline. Thus in the case of silicon, amorphous silicon materials and crystalline silicon materials can be utilized. In one specific aspect, the i-type layer is amorphous.

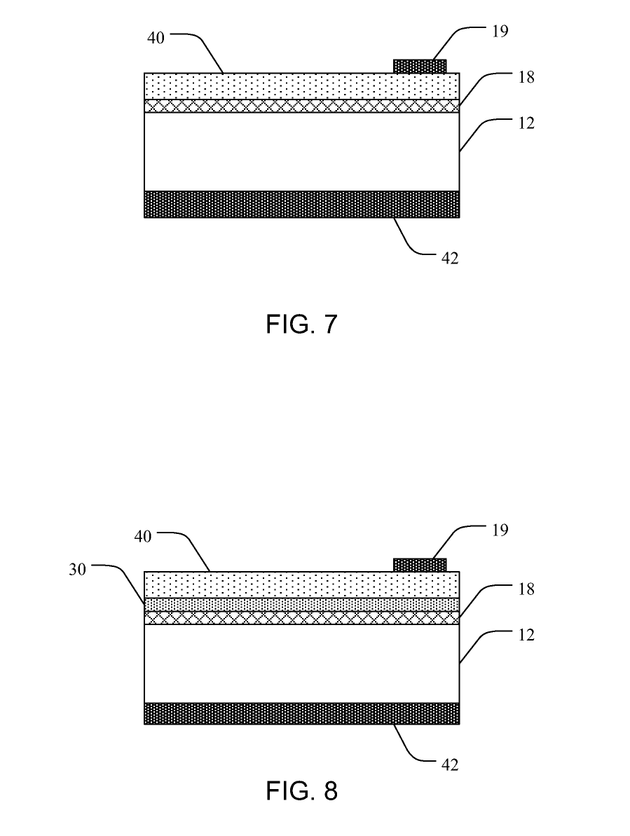

In another aspect of the present disclosure, a heterojunction photovoltaic device is provided (see for example, FIG. 7). Such a device can include a crystalline semiconductor layer 12, a doped semiconductor layer 40 coupled to the crystalline semiconductor layer to form a junction, and a laser processed semiconductor region 18 coupled to the crystalline semiconductor layer. In some aspects, at least a portion of the crystalline semiconductor layer can be doped to form a junction with the doped semiconductor layer. Additionally, in some aspects an electrical contact 19 can be electrically coupled to the doped semiconductor layer. In another aspect, an electrode layer 42 can be coupled to the crystalline semiconductor layer opposite the doped semiconductor layer. In yet another aspect, the laser processed semiconductor region can be disposed between the crystalline semiconductor layer and the doped semiconductor layer. An additional laser processed semiconductor region can't be disposed between the crystalline semiconductor layer and the electrode layer. Additionally, in some aspects an i-type layer 30 can be disposed between the doped semiconductor layer and the crystalline semiconductor layer as a shown in FIG. 8.

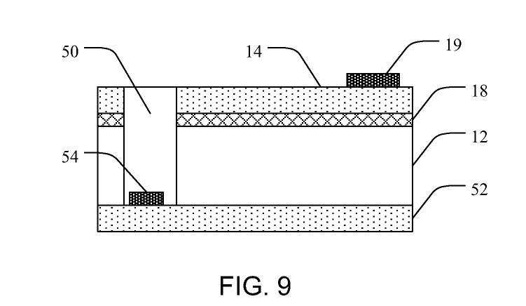

Various aspects of the present disclosure utilize electrical contacts. The utilization of electrical contacts in semiconductor devices is well known. In one aspect of the present disclosure, two electrical contacts can be utilized on opposite sides of the crystalline semiconductor layer. In some cases, however, it may be useful to utilize same side contacts. In such a configuration, both electrical contacts are accessible from the same side of the crystalline semiconductor layer. In one aspect, as is shown in FIG. 9, a trench 50 can be formed through a least the crystalline semiconductor layer 12 to the underlying doped semiconductor layer 52 or electrode layer (not shown). An electrical contact 54 is electrically coupled to the underlying doped semiconductor layer and access is provided from the front side via the trench. Though not shown in other embodiments, it is noted that the trench can be present in any of the embodiments or combination of embodiments shown in the FIGS., or in accordance with other embodiments of the present disclosure.

In another aspect of the present disclosure, a carrier or handler substrate can be utilized to facilitate manipulation of the device during manufacturing and possibly use. For example, a carrier substrate can be coupled to any of the doped semiconductor layers, the crystalline semiconductor layer, the electrode layer, or a combination thereof Such a carrier substrate can be made from any number of materials. Nonlimiting examples include glass, polymer materials, ceramic materials, metal foils, and combinations thereof. Additionally, in some aspects the carrier substrate can be flexible substrate. Such a flexible substrate can be useful in making and subsequently mounting heterojunction devices on a variety of surfaces. This may be particularly useful for non-planar surfaces. In one aspect, a flexible substrate can be a substrate having a measureable bend radius of curvature of less than or equal to 5 cm.

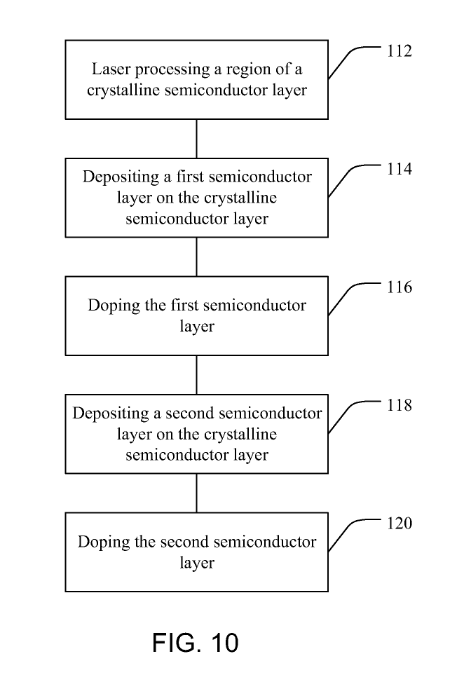

The present disclosure additionally provides methods of making heterojunction photovoltaic devices. In one aspect as is shown in FIG. 10, such a method can include, laser processing a region of a crystalline semiconductor layer 112, depositing a first semiconductor layer on the crystalline semiconductor layer 114, and doping the first semiconductor layer 116. The method further includes depositing a second semiconductor layer on the crystalline semiconductor layer 118 opposite the first semiconductor layer and doping the second semiconductor layer 120. In another aspect, the doping of at least one of the first semiconductor layer and the second semiconductor layer occurs in situ during deposition. It is also contemplated that doping of the semiconductor layers can occur as a separate step.

In another aspect, the method can include annealing the crystalline semiconductor layer and the laser processed region Annealing can enhance the semiconductive properties of the device, including increasing the photoresponse properties of the semiconductor materials. Although any known anneal can be beneficial and would be considered to be within the present scope, annealing at lower temperatures can be particularly useful. Such a “low temperature” anneal can greatly enhance the photoconductive gain and external quantum efficiency of heterojunction devices utilizing such materials. In one aspect, for example, the semiconductor materials can be annealed to a temperature of from about 300° C. to about 1100 ° C. In another aspect, the semiconductor materials can be annealed to a temperature of from about 500° C. to about 900° C. In yet another aspect, the semiconductor materials can be annealed to a temperature of from about 700° C. to about 800° C. In a further aspect, the semiconductor materials can be annealed to a temperature that is less than or equal to about 850° C.

The duration of the annealing procedure can vary according to the specific type of anneal being performed, as well as according to the various materials being used and additional desired results. For example, rapid annealing processes can be used, and as such, durations of the anneal may be shorter as compared to other techniques. Various rapid thermal anneal techniques are known, all of which should be considered to be within the present scope. In one aspect, the semiconductor materials can be annealed by a rapid annealing process for a duration of greater than or equal to about 1 μs. In another aspect, the duration of the rapid annealing process can be from about 1 μs to about 1 ms. As another example, a baking or furnace anneal process can be used having durations that may be longer compared to a rapid anneal. In one aspect, for example, the semiconductor materials can be annealed by a baking anneal process for a duration of greater than or equal to about 1 ms to several hours. As has been described, it may also be beneficial utilize semiconductor materials having a low oxygen content and to anneal such materials in a substantially oxygen-depleted environment.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A heterojunction photovoltaic device, comprising:
a crystalline semiconductor layer;
a first doped semiconductor layer coupled to the crystalline semiconductor layer;
a second doped semiconductor layer coupled to the crystalline semiconductor layer opposite the first doped semiconductor layer, wherein the first and second doped semiconductor layers form junctions with the crystalline semiconductor layer; and
a laser processed semiconductor region coupled to the crystalline semiconductor layer.

2. The device of claim 1, wherein the laser processed semiconductor region has a substantially textured surface with surface features having a size selected from the group consisting of micron-sized, nano-sized, and combinations thereof.

3. The device of claim 1, wherein the laser processed semiconductor region is disposed on the crystalline semiconductor layer between the first doped semiconductor layer and the crystalline semiconductor layer.

4. The device of claim 1, wherein the laser processed semiconductor region is disposed on the crystalline semiconductor layer between the second doped semiconductor layer and the crystalline semiconductor layer.

5. The device of claim 1, wherein the laser processed semiconductor region comprises:
a first laser processed semiconductor region disposed on the crystalline semiconductor layer between the first doped semiconductor layer and the crystalline semiconductor layer; and
a second laser processed semiconductor region disposed on the crystalline semiconductor layer between the second doped semiconductor layer and the crystalline semiconductor layer.

6. The device of claim 1, wherein the laser processed semiconductor region is formed within the crystalline semiconductor layer.

7. The device of claim 1, wherein at least one of the first doped semiconductor layer and the second doped semiconductor layer is a member selected from the group consisting of amorphous silicon, amorphous germanium, and combinations and alloys thereof.

8. The device of claim 1, wherein at least one of the first doped semiconductor layer and the second doped semiconductor layer is a crystalline semiconductor layer.

9. The device of claim 1, further comprising an i-type layer disposed between the crystalline semiconductor layer and at least one of the first doped semiconductor layer and the second doped semiconductor layer.

10. The device of claim 9, wherein the i-type layer is amorphous.

11. The device of claim 1, wherein the crystalline semiconductor layer includes a member selected from the group consisting of group IV materials, compounds and alloys comprising materials from groups II and VI, compounds and alloys comprising materials from groups III and V, and combinations thereof.

12. The device of claim 1, wherein the crystalline semiconductor layer is silicon.

13. The device of claim 1, wherein the crystalline semiconductor layer is a member selected from the group consisting of nanocrystalline, microcrystalline, multicrystalline, and combinations thereof.

14. The device of claim 1, wherein the crystalline semiconductor layer is monocrystalline.

15. The device of claim 1, wherein the crystalline semiconductor layer has a thickness from about 0.1 μm to about 50 μm.

16. The device of claim 1, wherein the crystalline semiconductor layer has a thickness less than or equal to about 10 μm.

17. The device of claim 1, further comprising a first electrical contact electrically coupled to the first doped semiconductor layer and a second electrical contact electrically coupled to the second doped semiconductor layer, the first electrical contact and the second electrical contact being same side contacts.

18. The device of claim 1, further comprising a first electrical contact electrically coupled to the first doped semiconductor layer and a second electrical contact electrically coupled to the second doped semiconductor layer, the first electrical contact and the second electrical contact being opposite side contacts.

19. The device of claim 1, wherein the crystalline semiconductor layer includes a member selected from the group consisting of float zone (FZ), Magnetic Czochralski (MCZ), Czochralski (CZ), deposited semiconductor material, and combinations thereof.

20. The device of claim 1, wherein the laser processed region has been formed in a substantially oxygen-depleted environment.

21. The device of claim 1, further comprising a carrier substrate coupled to either the first semiconductor layer or the second semiconductor layer.

22. The device of claim 21, wherein the carrier substrate includes a member selected from the group consisting of glass, polymer materials, ceramic materials, metal foils, and combinations thereof.

23. The device of claim 21, wherein the carrier substrate is a flexible substrate.

24. A heterojunction photovoltaic device, comprising:
a crystalline semiconductor layer;
a doped semiconductor layer coupled to the crystalline semiconductor layer to form a junction; and
a laser processed semiconductor region coupled to the crystalline semiconductor layer.

25. The device of claim 24, wherein the laser processed semiconductor region is disposed on the crystalline semiconductor layer between the doped semiconductor layer and the crystalline semiconductor layer.

26. The device of claim 24, wherein the laser processed semiconductor region is disposed on the crystalline semiconductor layer opposite the doped semiconductor layer.

27. The device of claim 24, wherein the laser processed semiconductor region comprises:
a first laser processed semiconductor region disposed on the crystalline semiconductor layer between the doped semiconductor layer and the crystalline semiconductor layer; and
a second laser processed semiconductor region disposed on the crystalline semiconductor layer opposite the doped semiconductor layer.

28. The device of claim 24, further comprising an i-type layer disposed between the doped semiconductor layer and the crystalline semiconductor layer.

29. The device of claim 28, wherein the i-type layer is amorphous.

30. The device of claim 24 wherein the doped semiconductor layer is a member selected from the group consisting of amorphous silicon, amorphous germanium, and combinations and alloys thereof.

31. The device of claim 24, wherein at least a portion of the crystalline semiconductor layer is doped.

32. A method of making a heterojunction photovoltaic device, comprising:
laser processing a region of a crystalline semiconductor layer;
depositing a first semiconductor layer on the crystalline semiconductor layer;
doping the first semiconductor layer;
depositing a second semiconductor layer on the crystalline semiconductor layer opposite the first semiconductor layer; and
doping the second semiconductor layer.

33. The method of claim 32, further comprising annealing the crystalline semiconductor layer and the laser processed region.

34. The method of claim 33 wherein the crystalline semiconductor layer has a low oxygen content, and the laser processing and the annealing are performed in a substantially oxygen-depleted environment.

35. The method of claim 33, wherein the annealing of the crystalline semiconductor layer and the laser processed region is performed to a temperature of from about 300° C. to about 1100° C.

36. The method of claim 33, wherein the annealing of the crystalline semiconductor layer and the laser processed region is performed to a temperature of from about 500° C. to about 900° C.

37. The method of claim 32, wherein the laser processing includes irradiating the crystalline semiconductor layer with laser radiation to form a substantially textured surface with surface features having a size selected from the group consisting of micron-sized, nano-sized, and combinations thereof.

38. The method of claim 37, wherein irradiating the crystalline semiconductor layer includes exposing the laser radiation to a dopant such that the irradiation incorporates the dopant into the crystalline semiconductor layer.

39. The method of claim 32, wherein the laser processing is performed using a pulsed laser including a member selected from the group consisting of a femtosecond laser, a picosecond laser, a nanosecond laser, and combinations thereof.

40. The method of claim 32, wherein the doping of at least one of the first semiconductor layer and the second semiconductor layer occurs in situ during deposition.

41. The method of claim 32, further comprising forming an i-type layer between the first semiconductor layer and the second semiconductor layer.
